(19) United States
(12) Patent Application Publication
(10) Pub. No.: US 2012/0126026 A1
(43) Pub. Date: May 24, 2012

(54) Moisture Probe and System

(76) Inventor: Steven Ernest Sparks, Garland, TX (US)

(21) Appl. No.: 12/953,581

(22) Filed: Nov. 24, 2010

(51) Int. Cl. A01G 27/00; G01R 27/26

(52) U.S. Cl. 239/64; 324/689

(57) ABSTRACT

An advanced landscape irrigation control system that integrates a soil moisture probe with a timer-based controller which can be used to directly control a single irrigation zone without need for a separate timer-based controller. The invention is equally capable of being installed as a soil moisture sensor that operates under the control of a traditional timer-based controller. The moisture probe and system disclosed in this invention is fully buried in the soil and electrically connected to the water solenoid-valve(s), measuring temperature and soil moisture content using a capacitive-based probe in determining water solenoid-valve(s) operation. The device has no user settings and requires no calibration, including determining optimal soil moisture content by a unique method of recognizing soil signatures, or the unique electrical response of soils to water.

### FIELD OF THE INVENTION

The present invention relates to a soil moisture sensor for use in a 24VAC landscape irrigation system. More specifically, the invention relates to a capacitive-based probe for measuring soil moisture coupled with the electronic circuitry for controlling the irrigation interval independent of any other means except 24VAC. A separate irrigation timer-based controller is not needed.

### BACKGROUND OF THE INVENTION

The maintenance of vegetative landscapes has for a relatively long time used automated irrigation systems for providing water to promote the growth of grasses, plants, and trees in the landscape. The irrigation system is generally operated by a clock/timer-based controller which provides individual programmable timed irrigation periods for the number of zones supported by that controller. The timer-based controller simply turns water “on” at the desired time and day and turns it “off” after the time interval has completed for an irrigation zone. The timer-based controller advances to the next zone and repeats the process until all zones are processed. It is necessary for healthy plant growth that automated irrigation systems not only apply sufficient water to maintain plant growth, but equally important that they don't over-water or under-water. Over-watering can promote various plant diseases, particularly in heavy clay-based soils and may not be apparent until the plant is irrecoverable. Under-watering of plants is also serious, however its symptoms usually present themselves very visibly and quickly and are often reversible if caught early enough.

The wastefulness of these systems is contributable to a number of factors, not the least of which is poor design and irrigation scheduling, resulting in excessive watering leading to runoff. Oftentimes poor design will require the scheduling to be increased across the entire zone just to get adequate coverage in a small or problem area. Considering that the basic timer-based irrigation system is universally agreed to be 30-50% or less efficient in irrigating a landscape, especially if it is not routinely maintained, it is easy to understand how improved products and methods are needed for improving the conservation of irrigation water. Irrigation water further accounts for between 30-50% of the typical household water consumption, amounting to tens of thousands of gallons of water used each year. Because timer-based irrigation controllers rely solely on a clock to turn the water solenoid-valve of an irrigation zone on and off during irrigation, there is no feedback mechanism to tell the controller whether water is even needed or how much additional irrigation is required. User's may try to adjust the timer based on some time limit, like 15 minutes per zone, or measure the systems output and apply ¼″ of water at each activation, but there are serious drawbacks to all of these approaches. To improve the efficiency of the irrigation system, factors like soil moisture content and environmental conditions must be taken into account.

Soil composition must also be taken into consideration to improve the efficiency of the system. Soil is not homogeneous in material content or in size of particles. Not only can soil contain mixtures of the three basic sizes of particles, clay, silt and sand, but various organic debris and rocks may also be present which further complicates the homogeneousness of soil. These various soil mixtures also have water holding forces to greater and lesser degrees. Also, soils do vary in composition across a landscape where a clay soil may naturally have some loam mixes, or there may be rock structures at varying depths under the soil surface. Further, it is not uncommon for homeowners to amend the native soils with sands, loams and organic material which make irrigation even more difficult due to differences in drainage. All these factors lead to the conclusion that it is impossible to determine adequate irrigation by only considering what can be seen at the surface. Additionally, in an urban or maintained landscape where fertilization is applied to promote plant growth, the salts in these products will increase the conductivity in the soil. As the conductivity increases, significant error in soil moisture determination by some sensing devices can occur whereby higher water content than is actually present may be erroneously detected.

Environmental conditions are also an important aspect to managing an efficient irrigation system. Temperature is one of the most important influences to monitor. Cooler temperatures require fewer watering intervals. Irrigation should be halted during freezing conditions to protect the irrigation system plumbing from damage and property owners from the liability of irrigation systems applying water which turns to ice on surfaces. Additionally, during high heat times of the day, irrigation should be avoided due to excessive evaporation, which results in a lower percentage of the irrigation water reaching the soil and plant roots. Rain, especially from an unexpected scattered thunderstorm, must be detected and its moisture must be accounted for in an irrigation cycle. Further, the radiant heating from the sun will result in higher evaporation rates on the west side of a landscape than on the east side of a landscape. None of these variables can be adequately accounted for by a timer-based controller.

Vegetation in a landscape will substantially influence the moisture content in the soil. For instance, xeriscape plants consume less water in their growth therefore require less moisture in the soil, whereas turf grasses or tropical plants consume significantly higher amounts of water in their growth, thereby requiring higher soil moisture content in the soil.

To combat these effects it has long been understood that the average person will manually turn the system on or off to account for the above mentioned variables. Obviously this is not a consistent or reliable way in managing landscape irrigation and leads to unpredictable management of water resources as well as possible damage to the vegetation in the landscape. Numerous inventions have been disclosed to manage soil moisture content. Inventions range from neutron probes which are expensive and use radioactive material, to evapotranspiration (ET) based systems which tend to be high to medium priced and use subscription services to acquire environmental conditions for use in calculations, to matric potential sensors and electrical resistance devices which are much lower cost but typically have a short life span and have a limited range of operation. Further, most of these have undesirable usage scenarios including difficult setup and complex calibration.

Due to the numerous solutions to water conservation for irrigation systems available to consumers along with the somewhat complex technology that these devices bring and the perception of low Return On Investment (ROI), residential and commercial sites appear to have resisted adopting this new technology en masse. It is understood that this invention must address and overcome these problems not capitalized upon by prior art.

### SUMMARY OF THE INVENTION

The limitations of prior art discussed above will be shown to be satisfied by the present invention through any of several aspects. In accordance with one aspect of the present invention, a soil moisture sensor is comprised of an improved capacitive-based sensor coupled with an integrated timer-based controller that is buried in the soil and operates one zone, or one water solenoid-valve, of an automated irrigation system. The device does not require the use of a separate irrigation system's wall mounted timer-based controller. The invention can be connected directly to 24VAC or similarly adapted to other low-voltage systems. The capacitive based probe is stimulated by periodic high frequency waveforms, the response of which is evaluated by the embedded microcontroller to determine moisture content of the soil. Because the microcontroller is incorporated within the invention itself and integral to its operation, and is not part of an additional or external device, it is understood to be embedded. Periodic sampling of the soil moisture content continues, during which time the water solenoid-valve is energized so that irrigation of the landscape is performed. Once samples are detected that sufficient soil moisture content exists, the water solenoid-valve is de-energized, and irrigation ceases. The device then goes into a low-power mode and sleeps for 24 hours. After 24 hours it awakens and once again checks the soil moisture to determine if more irrigation is needed.

My invention includes a means for controlling an irrigation system comprises an irrigation means for controllably supplying water to a monitored area of land; and a control means for controlling the irrigation means comprising a sampling means for sampling the moisture level of the soil of a particular point within the monitored area of land at predetermined times, and a command means for commanding the irrigation means to supply water to the land whenever the sampled moisture level is below a first predetermined level, and for commanding the irrigation means to cease supplying water whenever the sampled moisture level is above a second predetermined level.

My invention further includes a means for sensing the moisture of an area of soil comprising a pair of electrically-conductive plates arranged parallel to one another, separated by a predetermined distance, and buried into the area of soil in which moisture is to be sensed; at least one generator means for generating periodic high frequency electrical waveforms; at least one pair of conductive lead means for connecting the at least one generator means to each of the electrically-conductive plates; and a detector means for detecting the capacitance between the pair of plates when the generator means generates high frequency electrical waveforms.

My invention further includes a method of irrigating land comprising the steps of: (a) first, sampling the moisture level of a predetermined area of land and detecting the ambient temperature of the air over the predetermined area of land; (b) second, if the sampled moisture level of the predetermined area of land is below a preset value and if the detected ambient temperature of the air over the predetermined area of land is between a first and a second predetermined temperature, then causing the predetermined area of land to be irrigated; but, if the sampled moisture level is above the preset value or if the ambient temperature of the air over the predetermined area of land is not between the first and the second predetermined temperatures, then going to step (e) below; (c) third, during irrigation, periodically sampling the moisture level of the predetermined area of land until such time as the sampled moisture level is above the preset value; and subsequently (d) causing the irrigation of the land to cease, and (e) starting a predetermined time interval at the end of which the method will be repeated starting with step (a).

In another aspect, the device can be connected to the existing wall mounted timer-based controller of the irrigation system, where one device is connected to a single irrigation zone. Upon being powered-up by the timer-based controller, the device begins performing soil moisture content checks and thereby energizing the water solenoid-valve while the temperature is within acceptable upper and lower limits and the soil moisture content is determined to be less than optimal. The device operates as previously described as long as the timer-based controlled supplies power to the device. Once the tinier-based controller turns the power off due to its time interval expiring, the device powers down. In this configuration the timer-based controller overrides the clock/timer function of the device.

In a further aspect, the device can be connected to the existing wall mounted timer-based controller of the irrigation system, where one device is electrically connected to zones, being in a single location buried in the soil. Upon being powered-up by the timer-based controller the device begins performing soil moisture content checks and enabling the energizing of the water solenoid-valve in the zone as determined by the timer-based controller. When the location wherein the device is buried senses sufficient soil moisture or temperatures outside the temperature range, irrigation is disabled for all irrigation zones. As long as the soil moisture content is less than optimal, irrigation of all zones will proceed according to the zone sequencing and time limit specified in the timer-based controller. The device will operate as a rain sensor buried in the soil, instead of as the traditional roof mounted air-based sensor, operating all irrigation zones from a single device and location.

A further object of my invention includes lowering the cost of equipment ownership over traditional irrigation systems by eliminating the need for a separate clock/timer normally found in a timer-based controller of an irrigation system. Further, determining how to program and re-program these irrigation timer-based controllers is confusing and difficult to accomplish. This invention involves no user programming and only waters when the soil moisture content is deficient.

Another object of this invention is to provide a soil moisture sensor that is completely autonomous in its operation. This invention has an embedded microcontroller that handles all operations. The invention adapts to any soil type by its auto-calibration capability. The invention detects freezing temperatures and high heat/high evaporation periods and disables irrigation. The invention is able to operate over timed intervals based on an internal timer.

Another object of this invention is that of a low-power electronic sensor. The invention operates off of the existing low voltage wiring. Because it requires very little power, it has no impact on the existing irrigation system power requirements. This device is an energy saving device in three ways. First, during operation, sampling of the soil moisture content only occurs in thousandths of a second, significantly reducing power dissipation and emissions. Second, the device is powered down and sleeping approximately 59.95 seconds of every minute consuming only slightly more power than that to enable the water solenoid-valve. Third, once the irrigation cycle has completed, the device powers down all electronics except a clock/timer waiting for the 24 hour sleep period to expire. Although the device could be powered from batteries due to its very low power consumption, it does not so as to remove the need for routine battery replacement.

Another object of this invention is its small form factor and durability to reside in the soil indefinitely. The waterproof and rigid construction allows direct insertion in the soil without the need for special burial techniques or periodic maintenance.

The invention is a multi-functional device easily adapted to other mediums and applications such as water level sensing for automatic fill or shut-off of a water supply. Control of the level of water for pools, ponds, fountains, and hot water heater overflow are similar to that of moisture content in the soil. Use as a rain sensor to control a plurality of zones is also supported.

Additional objects and advantages will become apparent upon consideration of the following description and drawings.

### BRIEF DESCRIPTIONS OF THE DRAWINGS

FIG. 1 is a cross-section view of the present invention inserted in the soil.

FIG. 2 is a front view diagram of the preferred embodiment of the present invention.

FIG. 3 is a system level block diagram of the present invention.

FIG. 4 is a set of curves of the electrical response, or signature, of water being applied to soil.

FIG. 5 is a timing diagram of the timer/clock operation (24 hour interval).

FIG. 6 is a schematic circuit diagram of the electronic circuitry.

### DETAILED DESCRIPTION

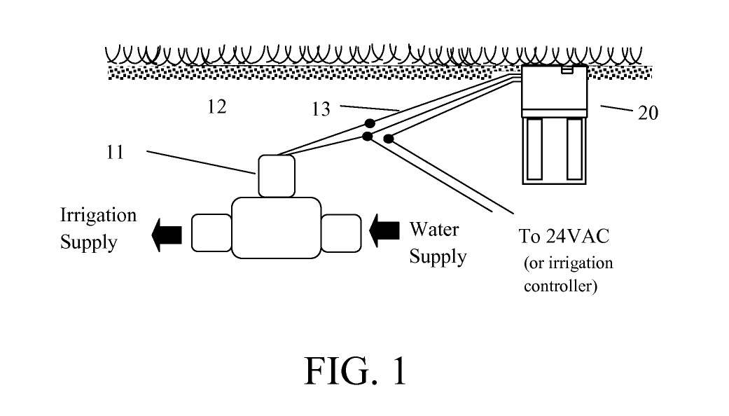

Referring to FIG. 1 an irrigation system is represented by a water solenoid-valve 11 and present invention 20 buried in soil 12 and is further electrically connected to each other with electrical wiring 13. The moisture probe and system 20, and water solenoid-valve 11 is further connected directly to 24VAC in a preferred embodiment.

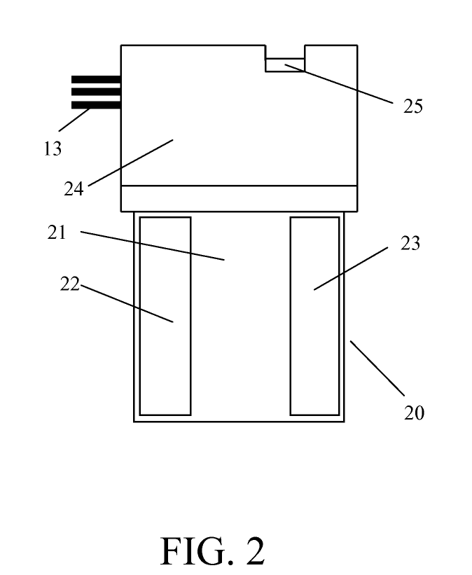

FIG. 2 illustrates a close-up representative scaling of the moisture probe and system 20 from FIG. 1. There are two primary components to the invention 20, the electronics housed in case 24, and the probe 21. The probe 21 is a substrate containing two conductive plates 22 and 23 that form two plates of a capacitor. This probe assembly 21 is further structurally and electrically connected to the electronics in case 24. The case 24 provides a protective environmental barrier for the electronics. A temperature sensing electrode 25 has been integrated as part of the electronics case 24. The wires 13 enter case 24 to provide power for the invention 20 and to control the water solenoid-valve 11.

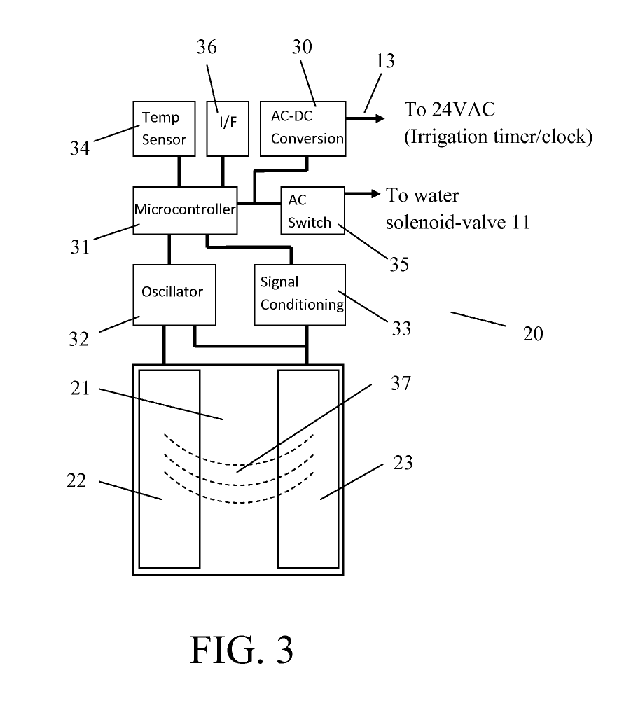

FIG. 3 provides yet a more detailed view of the electronics system inside the case 24 of the invention 20. The AC-DC conversion 30 brings in 24VAC through wires 13 and converts it to DC for use by the electronic circuitry. The AC-DC converter 30 is electrically connected to the embedded microcontroller 31, oscillator 32, signal conditioner 33, temperature sensor 34, AC switch 35, and I/F (interface) 36. Control and operation of the invention 20 is maintained by microcontroller 31 and its electrical connections to oscillator 32, signal conditioning 33, temperature sensor 34, AC switch 35, and interface 36.

The moisture probe system 20 in FIG. 1 is a subterranean irrigation control device that is employed in an irrigation system with a water solenoid-valve 11 to manage soil moisture levels. The invention 20 is intended to withstand harsh environmental conditions of being buried in the soil year-round. The construction of the moisture probe system 20 is comprised of the probe substrate 21 and waterproof casing 24 for protection of the electronics. The case 24 is manufactured of ABS, PVC, or a similar material that is UV resistant and impervious to water absorption and attack by fertilizer salts. The cavity of the case 24 is further filled with a polyurethane or similar material for moisture protection. The probes conductors 22 and 23, and temperature sensor conductors 25 are sealed in a polyurethane, fiberglass, or similar coating to prevent degradation of the conductors.

Further, in FIG. 2 the invention 20 is magnified to illustrate details. The case 24 encloses the electronic circuitry and is molded to accommodate several features. First, the case 24 has tapered edges on the bottom front and back sides to aide direct insertion into the soil. A notch in the top of the case 24 front and back is provided to accommodate a small temperature sensor probe 25 for ambient temperature or soil temperature readings. The probe 21 is comprised of a solid continuous material between conductive plates 22 and 23 to reduce breakage during insertion in soil. The case 24 and the probe 21 form a rigid structure allowing direct insertion into the soil without the need to pre-dig a hole. The depth of the invention 20 is optimally placed when the top of case 24 is even with the soil 12 surface making it impervious to damage by landscape maintenance. The preferred embodiment is credit-card sized making placement in a variety of locations practical.

The conductive plates 22 and 23 comprising the probe 21 are arranged in a planar configuration, both being on the same layer of the probe substrate 21. The wide conductive plates, approaching ½ inch in the preferred embodiment, have an approximate two plate width space between conductive plates 22 and 23. Advantages of the wide plate metal and wide spacing yield a greater capacitance that translates into greater differentiation of moisture readings and makes the conductive plates less affected by soil particle sizing and soil heterogeneity.

The operation of the invention 20 in FIG. 3 can best be explained from the perspective of the embedded microcontroller 31. The embedded microcontroller 31 provides control of the moisture probe 21 and electronic circuitry in sequence of execution. The microcontroller 31 also performs the appropriate power-down of circuitry to enforce low-power consumption.

The microcontroller 31 and other circuitry are powered-up after the AC-DC converter 30 receives 24VAC at its input through wires 13. Once the electronics are powered-up the embedded microcontroller 31 proceeds to initialize itself and the other electronics including oscillator 32, temperature sensor 34, and AC switch 35.

Following initialization, the microcontroller 31 will proceed to check the temperature sensor 34 and determine if the temperature is within an acceptable range for irrigation. Temperatures near freezing can lead to irrigation system damage and possible endangerment to the public if roadways and sidewalks are sprayed with water that turns to ice. Further, high temperatures increase evaporation rates leaving less water for the root zone and violating water conservation guidelines in some areas. The microcontroller 31 will avoid irrigation during these periods by using readings from the temperature sensor 34.

Once the microcontroller 31 has determined that the temperature is within range, it proceeds to enable irrigation. To enable irrigation involves the microcontroller 31 detecting low soil moisture content in the soil, and then energizing the water solenoid-valve 11. As long as low moisture content in the soil exists, irrigation is enabled.

Low soil moisture content is determined by the microcontroller 31 enabling oscillator 32, which then excites the probe 21 with a high frequency signal. This high frequency signal is then attenuated by the dielectric of soil, water, and air around the probe 21 of the conductive plates 22 and 23. This attenuated response is filtered by the signal conditioning 33 and then sampled by the microcontroller 31. The microcontroller 31 then performs an analysis of the sampled voltage to determine if the optimal soil moisture content exists. This energizing and de-energizing of probe 21 and sampling of the voltage by the microcontroller 31 continues to cycle until soil moisture content is determined to be adequately saturated.

The determination of what constitutes adequate soil moisture content by the microcontroller 31 must be configured. There are two possible methods of calibration, semi-automatic and automatic.

Semi-automatic calibration requires that an installation procedure be followed. The simple procedure first involves the installer applying power to the invention 20 before inserting it into the soil. Next the invention 20 is inserted into saturated soil with power remaining on for a brief period of time. The microcontroller 31 activates the oscillator 32 and the signal conditioning 33 to record readings from the probe 21 during this time. These saturated soil readings are then adjusted to account for variables like temperature, and stored as a final soil moisture content value used to determine irrigation on/off conditions.

Automatic calibration requires no installation procedure. The invention 20 is inserted directly in the soil and is ready to use. The microcontroller 31 recognizes that no soil moisture content value has been supplied through the semi-automatic calibration procedure, and proceeds to determine an optimal value during normal operation. This calibration process is an iterative procedure occurring over several irrigation cycles whereby the microcontroller 31 must store and analyze prior irrigation event readings before determining the final optimal reading. The microcontroller employs heuristic methods to track the infiltration of water over time through the soil past the probe 21. By observing multiple cycles of irrigation the microcontroller 31 can recognize a pattern, or signature, that is unique per soil type. It has been observed that the application of water to various soil types like sand, loam, and clay yield distinctive responses, but remain common to that soil type.

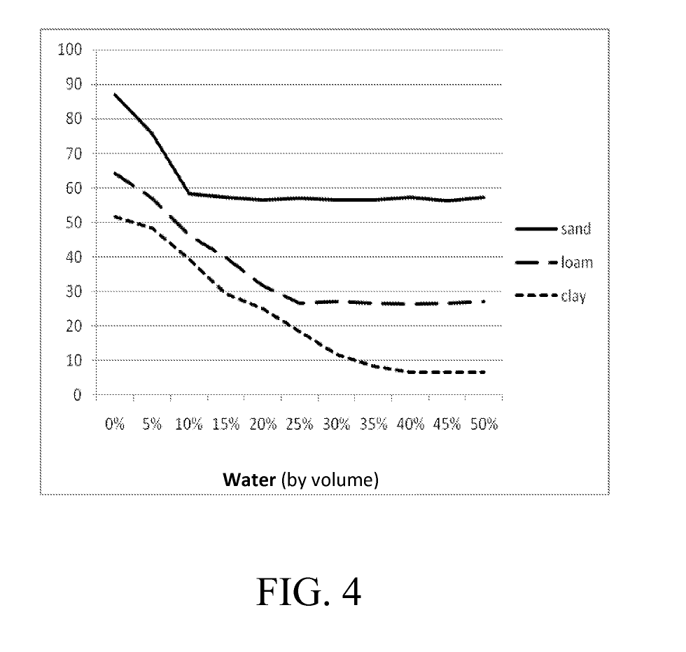

FIG. 4 can be used to illustrate. For the three soil types shown, it can be observed that each has a unique starting point at 0% water and unique ending points at fully saturated soil. So, as a soil type goes from a dry condition (no soil moisture) to a saturated condition (no more water can be added) it will have a starting point and ending point that falls on/near the curves shown. By measuring the slope of the curves and recognizing that the saturated soil end point of each type is unique, soil type can be generally classified for purposes of irrigation. The starting point, slope and end point forms the signature of the soil type. For purposes of simplicity, the slope of each line shown is based on normalized water application rates. Once a soil type is constructed from measurements, its values can be correlated to existing data for use in determining irrigation on/off values. The measurement used to define these curves is somewhat independent of the means and methods used to acquire them. In this example the invention 20 was used to generate the curves. By recording the resultant voltage due to the variable capacitance from the effects of soil, water, and air upon the invention 20, the curves were generated.

The automatic and semi-automatic calibration capabilities of the invention 20 allow it to be relocated within the landscape with no significant labor overhead or special setup knowledge. Additionally, the invention 20 can be used in any soil composition or elevation without regard for homogeneity or heterogeneity.

After calibration is complete and the microcontroller 31 has determined irrigation is needed, the microcontroller 31 enables the AC switch 35 to pass 24VAC to the water solenoid-valve 11. This enable signal remains active until adequate soil moisture content is detected by the microcontroller 31, at which time the enable signal to the AC switch 35 is removed. Disabling of the AC switch 35 results in 24VAC being blocked from reaching the water solenoid-valve 11, resulting in cessation of irrigation. Once irrigation has ceased, the microcontroller 31 then proceeds to deactivate the control electronics and thereby enter a low-power sleep mode for the remainder of the 24 hour period. At the end of the sleep period the microcontroller 31 awakens, initializes all control circuitry, and prepares for a new irrigation cycle.

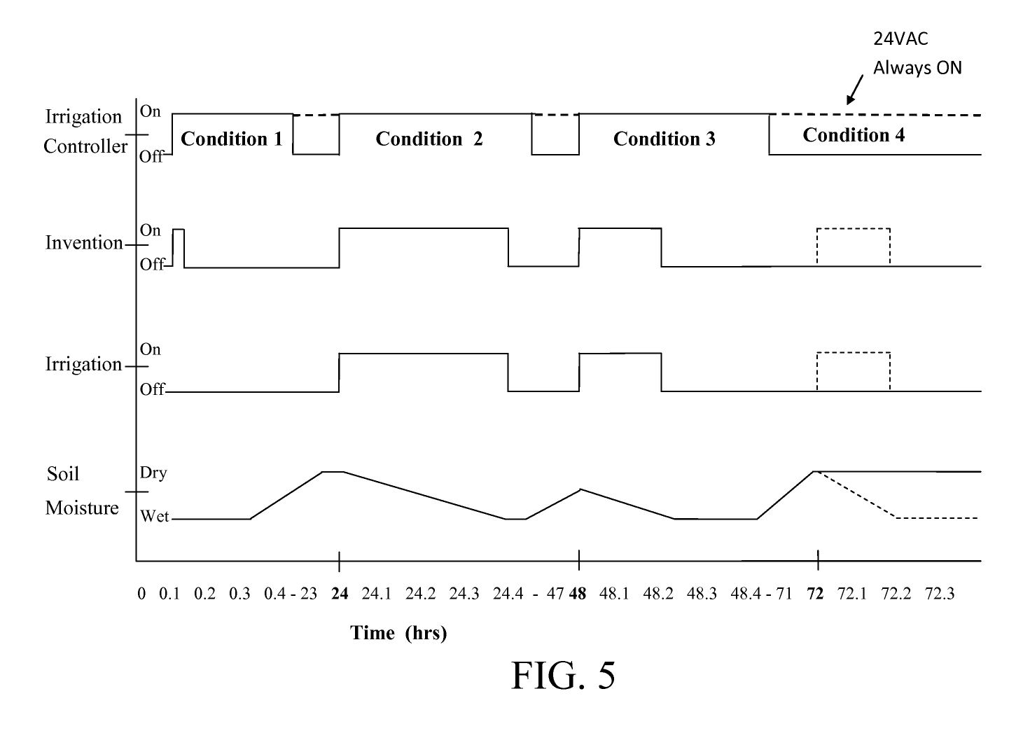

FIG. 5 illustrates the operation of the invention 20 over successive 24 hour periods. The moisture probe and system 20 integrates a soil moisture sensor and a clock/timer for interval based watering. The clock/timer is a peripheral of the microcontroller 31 further enabling the invention 20 to operate based on wall clock time for determining irrigation intervals. This allows it to be used in the absence of a traditional irrigation timer/clock.

FIG. 5 shows how the invention 20 functions with its internal clock/timer as well as in conjunction with an irrigation timer-based controller. Along the X-axis is time, and along the Y-axis are the items of interest including an Irrigation Controller, Invention 20, Irrigation status, and Soil Moisture. Each item on the Y-axis uses two line patterns to denote operation. The solid line pattern represents 24VAC being applied by an Irrigation Controller and the corresponding responses of the other Y-axis items. The dashed line reflects 24VAC being applied directly to the Invention 20, the Irrigation Controller being removed from the system, and the corresponding response of the other Y-axis items.

There are 4 timing areas of interest in FIG. 5, identified as conditions. Condition 1 represents the timing for the case of the Irrigation Controller enabling irrigation, but because the soil moisture=wet, the Invention 20 prevents further irrigation. Condition 2 represents the timing for the case again for the Irrigation Controller enabling irrigation. However, in this case, because the soil moisture=dry, the Invention 20 detects a need for irrigation and enables irrigation for 0.4 hours, or 24.4 on the X-axis. Note that this occurs in both the solid line and dashed line cases. Condition 3 illustrates that another 24 hour period has elapsed and the Irrigation Controller again turns on and expects irrigation to begin. The Invention 20 determines that additional irrigation can be applied and then enables irrigation. However, because the soil was already moderately moist, it did not need to irrigate for as long. In this case, the Invention 20 disabled irrigation after 0.2 hrs, or 48.2 hrs on the X-axis. It should be observed that for Conditions 1 through 3, the operation of the Invention 20 is the same whether the Invention 20 was connected directly to 24VAC or to an Irrigation Controller. Also, it can be seen from Conditions 1 through 3 that even though the Irrigation Controller was still providing power to the Invention 20, the Invention 20 disabled irrigation early due to soil moisture content. Condition 4 illustrates two cases of interest. The first case is shown by the solid line and illustrates that the Irrigation Controller does not turn power on after 24 hours has passed. Because it is assumed the Invention 20 is connected to the Irrigation Controller, it too will not turn on. Irrigation is not enabled even though the soil moisture=dry condition exists because 24VAC is not present at the Invention 20. The second case of Condition 4 represents a continuous 24VAC being available to the Invention 20 (Irrigation Controller is not present). The Invention 20 therefore turns on 24 hours after it was last on (72 hrs elapsed marker on X-axis) and proceeds to check for adequate soil moisture. Irrigation is enabled because soil moisture=dry. Irrigation is enabled until adequate soil moisture is again detected.

Further, the invention 20, is able to perform automatic correction of the irrigation start times. If during an irrigation event, the temperature rises past the high temperature point, the microcontroller 31 will stop the irrigation event. Upon termination of irrigation due to temperature, the microcontroller 31 calculates an offset start time for the next 24 hours irrigation period. This offset is simply ensuring that irrigation begins earlier in the day of the following period before the high temperature part of the day is expected. This feature would prove beneficial in preventing irrigating during the heat of the day, and thereby potentially receiving a citation for irrigating during prohibited hours, in those areas enforcing watering restrictions. Power failures, especially resulting from severe weather, will often reset the clock of an irrigation controller resulting in unintentional irrigation times.

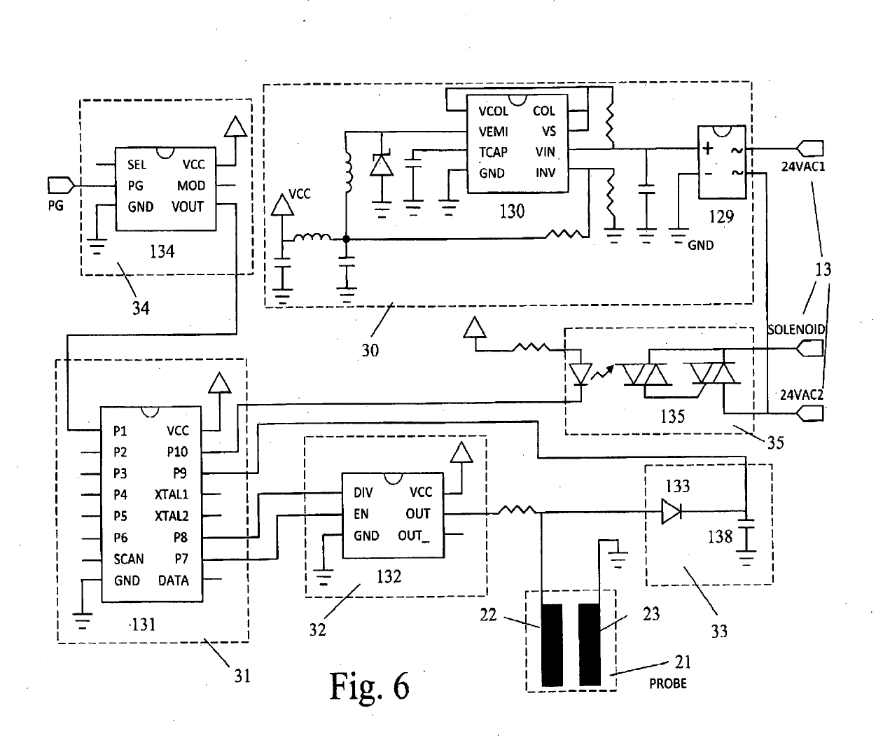

FIG. 6 describes a similar system with component level details and principles of operation.

The AC-DC conversion 30 is a high efficiency step-down converter integrated circuit 130 with biasing components to reduce 24VAC to 3VDC, thereby minimizing power dissipation of the electronics. Minimizing heating of the circuitry extends the life of the invention 20 and eliminates heating of the surrounding soil which can lead to erroneous soil moisture readings. The invention draws a very small amount of parasitic power from the 24VAC line, approximating less than 10 mA. This is essentially parasitic power that will not interfere with nor violate the irrigation system's current-draw rating. The microcontroller 31 performs a supervisory role in managing power dissipation of the electronic circuitry of the invention 20.

The microcontroller 31 is component 131 and is connected to temperature sensor 34 component 134. The output of the temperature sensor 134 is periodically sampled by the microprocessor 131. There is a trip point for both low temperature and high temperature that will disable irrigation operation of the invention 20. Representative temperatures of 33 F for low temperature and 95 F for high temperature are sufficient.

The microcontroller 131 is connected to the oscillator 32 component 132 enable signal. Upon receiving an enable signal, the oscillator 132 begins generating fixed-frequency signal pulses in the Very High Frequency (VHF) range. The oscillator 132 output is connected to the probe 21 so that a 3V peak to peak clock signal begins the charging and discharging of the conductive plates 22 and 23. The probe 21 is further connected to the signal conditioning circuit 33 comprising a high speed diode 133 and capacitor 138 for detecting peak voltage. The resultant voltage from the charging and discharging of the probe 21 is rectified by the high-speed diode 133 and capacitor 138 and made available to the microcontroller 131 input. The voltage sampled by the microcontroller 131 is then correlated to soil moisture content data in permanent memory, to determine when to turn irrigation on and off.

The VHF frequency is important for several reasons. The VHF frequency is critical in minimizing the influence of the excitation of salts and other ions in the soil from the electric field 37 on soil moisture readings. VHF excitation also unfortunately increases Electromagnetic Interference (EMI) and can disrupt electronic signals and promote heating of the soil. To remedy this effect, the embedded microcontroller 131 activates the oscillator 132 successively for very short durations. As an example, the ratio of the oscillator 132 being active to inactive is a ratio of 1:1000. That is, for every one second it is active or “on”, it is inactive or “off” for 1000 seconds. This drastically reduces power consumption and the duration of negative effects of EMI. The embedded microcontroller 131 and electronic circuitry also enter a low-power, or idle state, during the “off” time further reducing power and emissions. This “off” time is possible because the application and movement of water through the soil is relatively slow thereby eliminating the need for constant real-time monitoring.

The probe 21 having conductive plates 22 and 23 operate as a variable capacitor. The variable capacitor nature of the probe 21 results in the variable voltage detected by the microcontroller 31. The action of the probe 21 being a variable capacitor is achieved by the combination of soil, moisture and air effectively being a variable dielectric. Simply put, as water is applied to the soil, air is displaced. The displacement of air by water results in a higher capacitance. This increased capacitance results in a lower signal voltage across the probe 21. The electric field 37 of the probe 21, and hence the dielectric volume measured, is primarily that which is on the top side of the probe 21 between conductive plates 22 and 23 as shown in FIG. 3. This change in voltage is detectable at the microcontroller 131 and used in determining soil moisture content.

As the microcontroller 131 continuously evaluates irrigation needs it also enables the water solenoid-valve 11. The microcontroller 131 is connected to an opto-isolator and triac component 135 of the AC switch 35. When the microcontroller 131 determines irrigation is needed, it enables current flow thru the light emitting diode of the opto-isolator and triac 135 which then enables commutation of 24VAC across the triac of the opto-isolator and triac 135. Because the opto-isolator and triac 135 act similarly to a switch, and the water-solenoid valve is connected in series with it, current flows through the solenoid of the water solenoid-valve 11. When current flows through the water solenoid-valve 11 it enables passage of water through the irrigation lines to the sprinkler heads. In similar fashion, when the microcontroller 131 determines sufficient soil moisture content, it disables current flow through the opto-isolator and triac 135, and irrigation ceases. This end of an irrigation cycle would proceed to place the microcontroller 131 into a 24 hour sleep period before it attempts the next irrigation cycle.

The invention 20, also employs the microcontroller 31 to save off critical measured values recorded during operation. This capability, called a data-logger, comprises the microcontroller 31 saving measured values to permanent memory. Examples of values stored include temperature, probe readings, and time. This information is useful in managing future irrigation cycles and is accessible by the user through the I/F 38 interface.

In another embodiment, although not detailed in the Figures, I/F 38 in FIG. 3 is an interface port whereby a user can access the microcontroller 31 either through a serial bus or wireless means. A host system with either serial bus or wireless transmit and receive hardware would then be used to interrogate the values stored by the invention 20. Accessing this data would allow modification of program means of the invention thereby providing the ability to modify irrigation intervals and duration profiles. Additionally, soil components like fertilizer levels in the soil may also be tracked as they do have a slight correlation to soil moisture content readings.

It will be apparent that other embodiments and modifications of this invention can be realized after consideration of the content of this document. Therefore, the embodiments disclosed are to be exemplary only, and the claims below are the only limitations of this invention.

I claim:

1. A means of controlling an irrigation system comprising:
a controllable irrigation means for supplying water to a monitored area of land; and
a control means for controlling the irrigation means, the control means comprising an integrated soil moisture probe sensor, control logic, and a clock/timer for regulating the amount of water applied and the time interval of application; and
a control means for coupling to a low voltage electrical power lines and irrigation water solenoid-valve.

2. A means of controlling an irrigation system in accordance with claim 1 further comprising a rigid or semi-rigid circuit board attaching the moisture probe and electronics dimensionally in the range of 2 inches by 3.5 inches.

3. A means of controlling an irrigation system in accordance with claim 1 further comprising a pre-formed shell as a waterproof housing of control means electronics:
a control circuit on said substrate encased in a waterproof and rigid shell of ABS or similar material and further filled with a waterproof compound of polyurethane or similar;
wherein the waterproof shell further has a cut-out or notch in the top side of front and back side of the shell for a temperature sensor conduction pad that can be exposed to ambient temperature;
wherein the waterproof shell further has tapered bottom, front and back side;
wherein a plurality of wires for power and control means extends from the pre-formed shell.

4. A means of controlling an irrigation system in accordance with claim 1 further comprising an integrated temperature sensor coupled to the control means to allow activation of the irrigation means when ambient temperature is within an acceptable temperature range above freezing and below high evaporation points, outside of which irrigation means are disabled.

5. A means of controlling an irrigation system in accordance with claim 1 further comprising a self-calibrating means for establishing dry to wet soil moisture conditions:
a self-calibrating means for establishing dry to wet soil conditions for heterogeneous soil compositions; and
a means for detecting and quantifying unique soil responses, or signatures, to application of water for purposes of determining and characterizing soil moisture content levels; and
a means for calculation of soil moisture content through utilizing soil response signatures; and
a self-calibrating means allowing for no user intervention or settings.

6. A means of controlling an irrigation system in accordance with claim 1 further comprising a program of the control means for the embedded microcontroller and electronic circuitry which implements a clock to provide 24 hour interval irrigation control:
a clock means integrated in the device itself that can operate in conjunction with/or be overridden by an additional or external standard irrigation timer; and
a clock means integrated in the device itself that can manage timed irrigation intervals without need for additional or external electronics containing and operating as a clock or timer mechanism; and
a clock means integrated in the device itself that can operate in conjunction with the integrated soil moisture probe sensor as a timer for per zone irrigation; and
a clock means that will automatically adjust a 24 hour irrigation interval clock by retarding clock or timed interval of a subsequent 24 hour period to start earlier by 8 hours based on temperature measurements.

7. A means of controlling an irrigation system in accordance with claim 1 wherein said control of embedded microcontroller and peripheral electronic circuitry are optimized as a energy saving device by entering a low-power energy efficient mode to “sleep” for all non-essential time periods:
a low-power “sleep” mode is entered for the duration of a 24 hour irrigation cycle interval clock and will “wake” and activate at the conclusion of the 24 hour period; and
a low activation mode of the soil moisture probe wherein activation is a range of 1:1000 duty cycle such that a typical oscillator “on” time and soil moisture monitoring period is in the range of 10 milliseconds and the oscillator “off” time is in the range of 10 seconds, repeating for the duration of the irrigation interval.

8. A means for controlling an irrigation system in accordance with claim 1 wherein said control means embedded microcontroller and electronic circuitry implement a data-logger function to store operational information from the irrigation cycle to permanent memory that can further be accessed by the program or user through a serial bus or wireless means and further allow for modifying the operation of the device.

9. A means for controlling an irrigation system, comprising:
a) an irrigation means for controllably supplying water to a monitored area of land; and
b) a control means for controlling the irrigation means comprising:
1. a sampling means for sampling the moisture level of the soil of a particular point within the monitored area of land at predetermined times; and
a command means for commanding the irrigation means to supply water to the land whenever the sampled moisture level is below a first predetermined level, and for commanding the irrigation means to cease supplying water whenever the sampled moisture level is above a second predetermined level.

10. A means for sensing the moisture of an area of soil comprising:
a) at least one pair of electrically-conductive plates arranged parallel to one another, separated by a predetermined distance, and buried into the area of soil in which moisture is to be sensed;
b) at least one generator means for generating periodic high frequency electrical waveforms;
c) conductive lead means for connecting the at least one generator means to each of the electrically-conductive plates; and
d) a detector means for detecting the capacitance between the pair of plates when the generator means generates high frequency electrical waveforms.

11. A method of irrigating land comprising the steps of:
a) first, sampling the moisture level of a predetermined area of land and detecting the ambient temperature of the air over the predetermined area of land;
b) second, if the sampled moisture level of the predetermined area of land is below a preset value and if the detected ambient temperature of the air over the predetermined area of land is between a first and a second predetermined temperature, then causing the predetermined area of land to be irrigated; but, if the sampled moisture level is above the preset value or if the ambient temperature of the air over the predetermined area of land is not between the first and the second predetermined temperatures, then going to step (e);
c) third, during irrigation, periodically sampling the moisture level of the predetermined area of land until such time as the sampled moisture level is above the preset value; and subsequently
d) causing the irrigation of the land to cease, and
e) starting a predetermined time interval at the end of which the method will be repeated starting with step (a).
